(19) United States
(12) Patent Application Publication
(10) Pub. No.: US 2011/0305846 A1
(43) Pub. Date: Dec. 15, 2011

(54) APPARATUS AND METHOD FOR SURFACE PROCESSING

(75) Inventors: JUNG-CHEN CHIEN, Hsinchu County (TW); HUNG-JEN YANG, Hsinchu City (TW); CHIH-CHEN CHANG, Taipei County (TW); SHIH-CHIN LIN, Taipei City (TW); MUH-WANG LIANG, Miaoli County (TW)

(73) Assignee: Industrial Technology Research Institute, Hsinchu (TW)

(21) Appl. No.: 12/885,018

(22) Filed: Sep. 17, 2010

(30) Foreign Application Priority Data
Jun. 11, 2010 (TW) 099119008

(51) Int. Cl. C23C 16/503; C23C 16/50; C23C 16/02; C23C 16/00

(52) U.S. Cl. 427/534; 118/723 R; 118/723 E; 427/569

(57) ABSTRACT

The present disclosure provides a surface processing apparatus, comprising a reaction chamber provided to form a deposition layer on a substrate, a carrying chamber connected to the reaction chamber and comprising a slot, and a plasma generator installed in the slot and providing plasma to process the substrate surface. Whereby the disclosure further provides a surface processing method, which flatten surface of a deposition layer on the substrate when the substrate is carried form the reaction chamber to the carrying chamber after the deposition process in the reaction chamber.

### TECHNICAL FIELD

The present disclosure relates to a surface processing apparatus, and more particularly, to a surface processing apparatus and its method to flatten surface of a deposition layer on a substrate by using plasma.

### TECHNICAL BACKGROUND

In the conventional thin-film process, a plasma generator is set between a carrying and a reaction chambers, so that a substrate can be surface-cleaned, dry-etched, or surface-activated in the substrate-carrying process before carried into the reaction chamber.

However, when a ZnO layer is deposited using the LPCVD (low pressure chemical vapor deposition) process, the ZnO surface is often formed in pyramid or the like with sharp tips. The fact would consequently be disadvantageous for the following fabrication process, due to worse interfacial coverage and adherence, especially in the applications of the high conversion efficiency silicon thin-film solar cell.

In a prior art disclosed in U.S. Pat. No. 6,855,908, a local plasma etching method implements on a surface of a glass substrate to be processed. By controlling the amount of plasma etching in accordance with the peaks on the substrate surface, a flatness of 0.04-1.3 nm/cm² of the surface can be achievable. The U.S. Pat. No. 5,254,830 discloses a system for removing material from semiconductor wafers, which records memory information of the wafer surface and uses a plasma etching mechanism to remove the material surpassing a threshold thickness, whereby the wafer surface or the thickness of the deposited oxide can be uniformed. The U.S. Pat. No. 6,541,380 discloses a plasma etching process for metals and metal oxides deposited on a substrate, which forms a mask layer with apertures, and then etches the metal or metal oxide through the apertures by the plasma. The U.S. Pat. No. 7,390,731 discloses a oxide film deposition method, which setups a plasma generator in the reaction chamber to increase the deposition efficiency without in high-temperature conditions. Moreover, the U.S. Pat. No. 5,545,443 discloses a chemical vapor deposition process, which forms a transparent conductive ZnO film on a substrate, characterized by radiating UV light on the substrate during the deposition process, whereby the reaction efficiency and the film quality are improved.

### TECHNICAL SUMMARY

The present disclosure provides a surface processing apparatus, which comprises a reaction chamber, a carrying chamber connected to the reaction chamber, and a plasma generator provided in the carrying chamber. The apparatus generates plasma to process a deposition layer on a substrate carried from the reaction chamber to the carrying chamber, so as to improve surface characteristics of the deposition layer and to eliminate possibly formed defects. The plasma generator may work in atmospheric or vacuum conditions. A plasma generator of a thin rectangular shape is used to provide a large-area flattening process for substrate surface effectively.

According to one aspect of the present disclosure, an embodiment provides a surface processing apparatus comprising: a reaction chamber provided to form a deposition layer on a substrate and having a first opening; a carrying chamber connected to the reaction chamber and comprising a slot, a second opening corresponding to the first opening, and a carrying means provided inside the carrying chamber to carry the substrate from the carrying chamber to the reaction chamber or from the reaction chamber to the carrying chamber; a plasma generator installed on the slot; and a control unit electrically connected to the plasma generator and provided to control the plasma generator to generate plasma; wherein the plasma processes the deposition layer on the substrate carried from the reaction chamber to the carrying chamber.

According to another aspect of the present disclosure, an embodiment provides a surface processing method comprising: providing a surface processing apparatus comprising a reaction chamber, a carrying chamber, and a plasma generator, the carrying chamber connected to the reaction chamber and comprising a slot, the plasma generator installed on the slot; providing a substrate carried from the carrying chamber to the reaction chamber; carrying the substrate from the reaction chamber to the carrying chamber; and the plasma generator generating plasma to process the deposition layer on the substrate carried from the reaction chamber to the carrying chamber.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1A is a schematic diagram showing the structure of a surface processing apparatus according to an embodiment of the present disclosure.

FIG. 1B is a schematic structure of the deposition layer on the substrate.

FIG. 1C is a schematic diagram showing the structure of a surface processing apparatus according to another embodiment of the present disclosure.

FIGS. 2A and 2B are respectively a cross-sectional and a three-dimensional exploded views of the plasma generator according to a first exemplary embodiment.

FIG. 2C is a schematic diagram showing the layout structure of through holes in dual parallel lines according to the exemplary embodiment.

FIGS. 3A and 3B are respectively a cross-sectional and a three-dimensional exploded views of the plasma generator according to a second exemplary embodiment.

FIGS. 4A and 4B are respectively schematic diagrams of the deposited layers before and after the surface process.

FIG. 5 is a schematic flowchart of a surface processing method according to an embodiment of the present disclosure.

FIGS. 6A and 6B are the measured data of the deposited layers with and without the proposed surface processing method.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

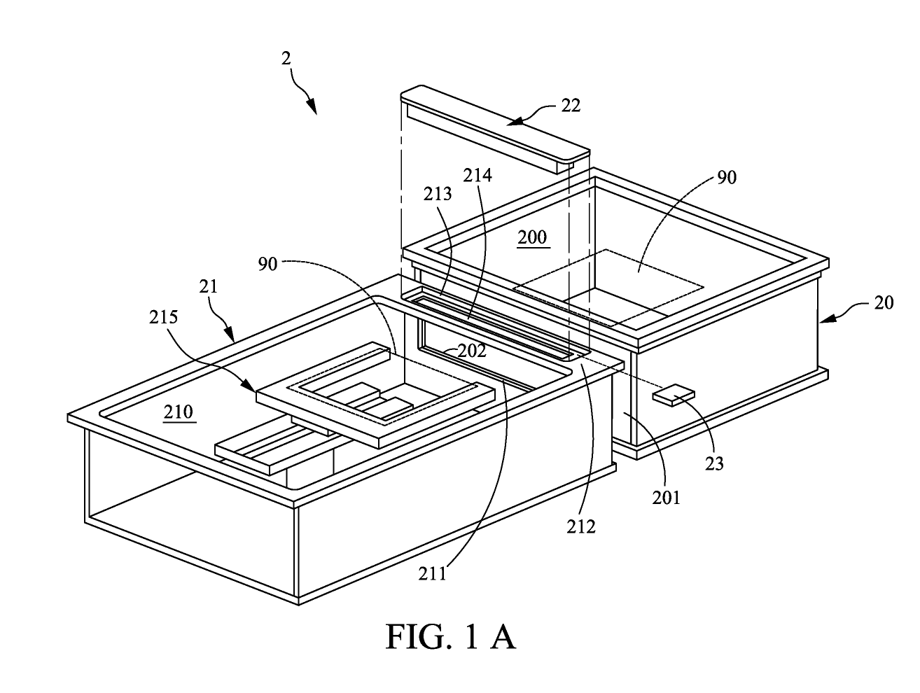

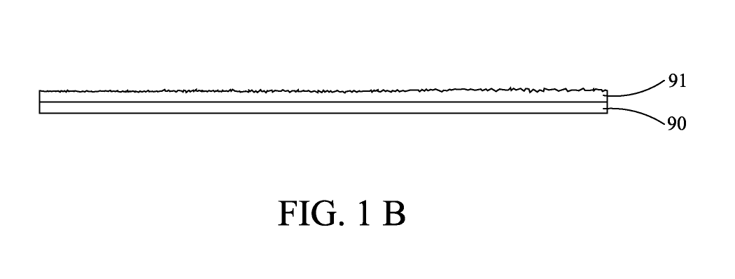

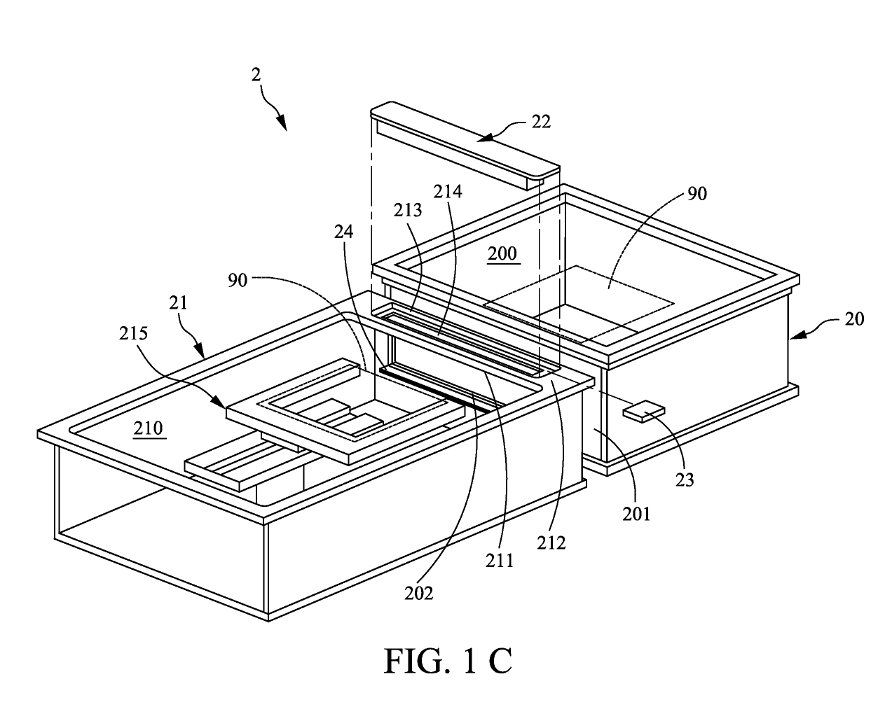

Please refer to FIG. 1A, which is a schematic diagram showing the structure of a surface processing apparatus according to an embodiment of the present disclosure. The surface processing apparatus 2 is composed of a reaction chamber 20, a carrying chamber 21, a plasma generator 22, and a control unit 23. In the reaction chamber 20, a space 200 is provided for a substrate 90 to be processed. A deposition layer 91 can be formed on the substrate 90 by a deposition process in the reaction chamber 20. A structure of the deposition layer 91 on the substrate 90 is schematically shown in FIG. 1B. In the embodiment, the deposition process can be LPCVD, but is not limited thereby, which can be the other CVD (chemical vapor deposition) method such as a plasma-enhanced CVD. Furthermore, the deposition layer 91 is made of a metal-oxide material such as ZnO, but is not limited thereby. There is a first opening 202 on the side wall 201 of the reaction chamber 20, for a substrate to be carried in and out of the reaction chamber 20.

The carrying chamber 21 is jointed to the reaction chamber 20 with their respective inner spaces 210 and 200 are coupled together. In this embodiment, a second opening 211 on the side wall of the carrying chamber 21 corresponds to the first opening 202 of the reaction chamber 20, so that a substrate 90 can be carried from the second opening 211 through the first opening 202 into the reaction chamber 20. Also, there is a slot 214 on the upper wall of the carrying chamber 21 and close to the reaction chamber 20, whereby the plasma generator 22 can be set on the carrying chamber 21 and coupled jointly to the space 210. A carrying means 215 is installed in the carrying chamber 21 to carry a substrate 90 from the carrying chamber 21 into the reaction chamber 20 or from the reaction chamber 20 into the carrying chamber 21. The carrying means 215 can be realized by any carrying mechanism, such as a conveyor belt, a robotic arm, or a conveyor with at-least-two-dimensional movement.

The plasma generator 22, set on the slot 214 on the upper wall 212 of the carrying chamber 21, can generate plasma in atmospheric or vacuum conditions. The slot 214 is patterned in accordance with the structure of the plasma generator 22, and is located in accordance with the practical requirements. In this embodiment, the slot 214 is located to approach the second opening 211, and the plasma generator 22 is in a thin rectangular shape. To enhance the performance of the plasma generator 22, in another embodiment, a metal plate 24 is set in the carrying chamber 21 and in a place corresponding to the plasma generator 22, as shown in FIG. 1C.

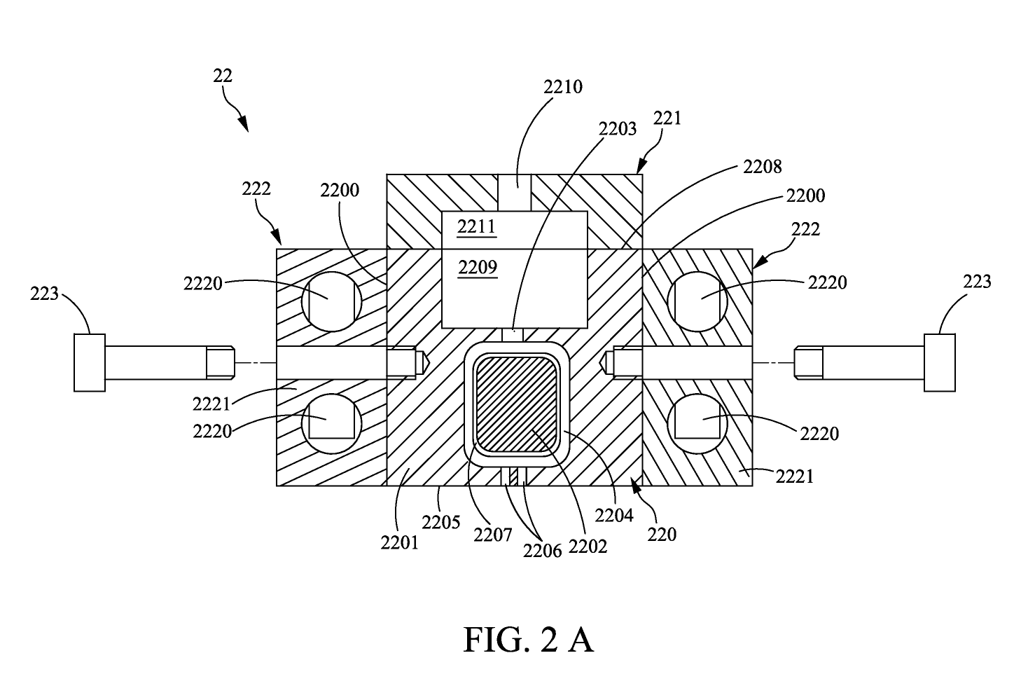

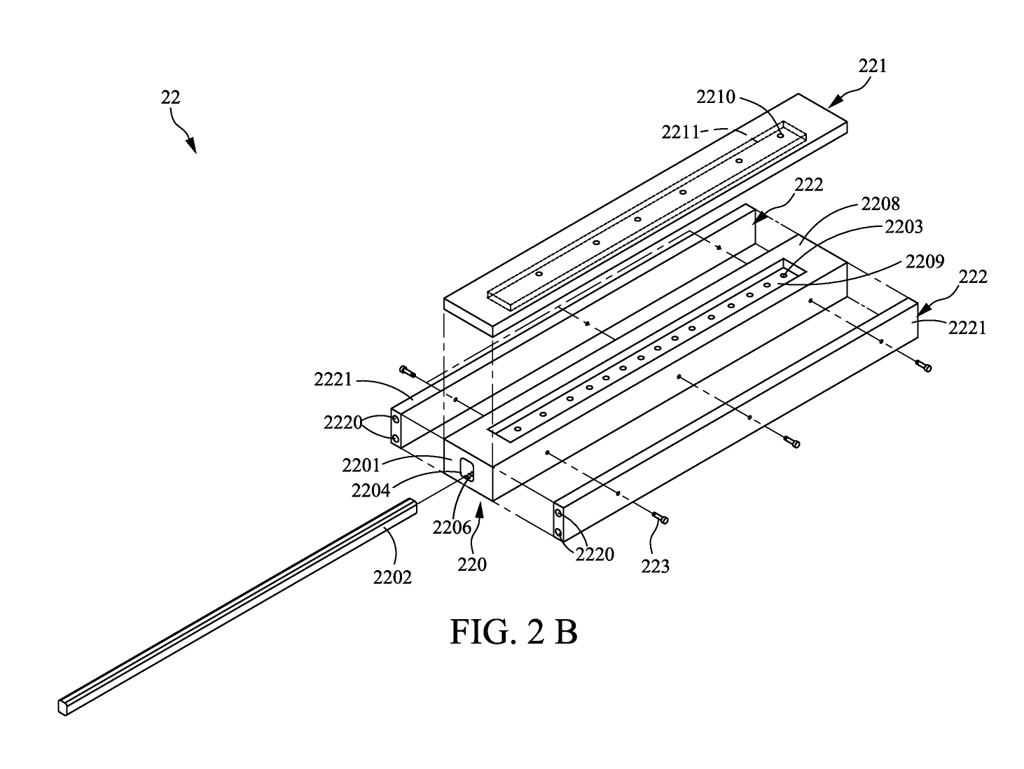

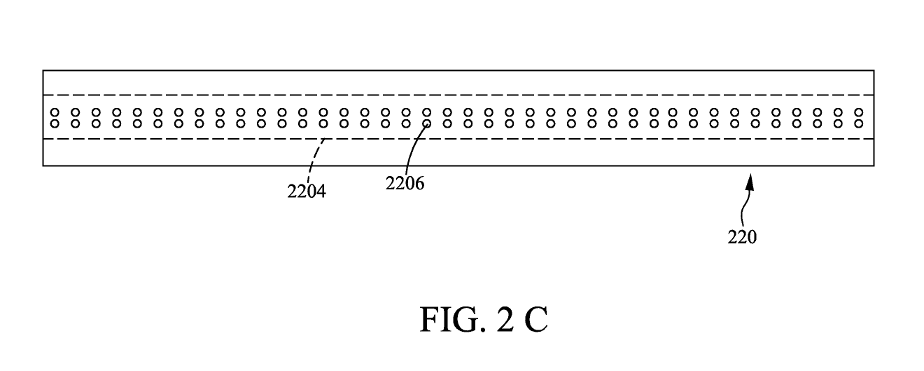

Referring to FIGS. 2A and 2B, these are respectively a cross-sectional and a three-dimensional exploded views of the plasma generator 22 according to a first exemplary embodiment. The plasma generator 22 is composed of a plasma module 220 with a negative electrode 2201 and a positive electrode 2202. The negative electrode 2201 is shaped in a rectangular solid and installed in the slot 213 and through the slot opening 214. The negative electrode 2201 is composed of a first gas vias 2203 and an accommodating channel 2204; the accommodating channel 2204 is connected to the first gas vias 2203 and accommodates the positive electrode 2202. The accommodating channel 2204 has multiple through holes 2206 on a first facet 2205 of the negative electrode 2201. A dielectric layer 2207 is coated on surface of the positive electrode 2202. In this embodiment, the through holes 2206 are laid out in dual parallel lines, for example, as shown in FIG. 2C, but is not limited thereby. It is noted that the through holes 2206 can also be laid out in at least one line, according to the practical needs. The cross-sectional shape of the positive electrode 2202 can be also circle or semi-circle, but is not limited thereby, which can be a combination of two arcs of different radii.

Furthermore, to increase uniformity of the mixed gas from the first gas vias 2203 into the accommodating channel 2204 to react with the positive electrode 2202 so as to produce plasma more efficiently, at least one gas balancing groove 2209 is further installed on a second facet 2208 corresponding to the first facet 2205 of the negative electrode 2201. The gas balancing groove 2209 is connected to the first gas vias 2203 jointly. A cover 221 is disposed on the second facet 2208. A plurality of gas entrance holes 2210 is formed on the cover 221, corresponding to the second facet 2208, to provide at least one reaction gas to flow into the plasma module 220.

After the reaction gases enter the gas balancing groove 2209 through the gas entrance holes 2210, the reaction gases are pre-mixed therein to be more uniform and enter the accommodating channel 2204 through the first gas vias 2203, and then are ionized to produce the plasma by the high electrical voltage between the positive 2202 and negative 2201 electrodes. The dielectric layer 2207 is used to decrease the magnitude of the plasma to further control etching ability of the plasma. In the embodiment, a recess 2211 is set under the cover 221, corresponding to the gas balancing groove 2209. It should be noted that the recess 2211 is an optional component and is set according to practical conditions. A cooling unit 222 is further installed on the negative electrode 2201, corresponding to the two opposite sides of the accommodating channel 2204. The cooling unit 222 is at least composed of a thermal dissipation plate 2221, which is fixed to the side face 2200 corresponding to the negative electrode 2201 by a fixer 223, such as a screw. A cooling piping 2220 is set in the thermal dissipation plate 2221.

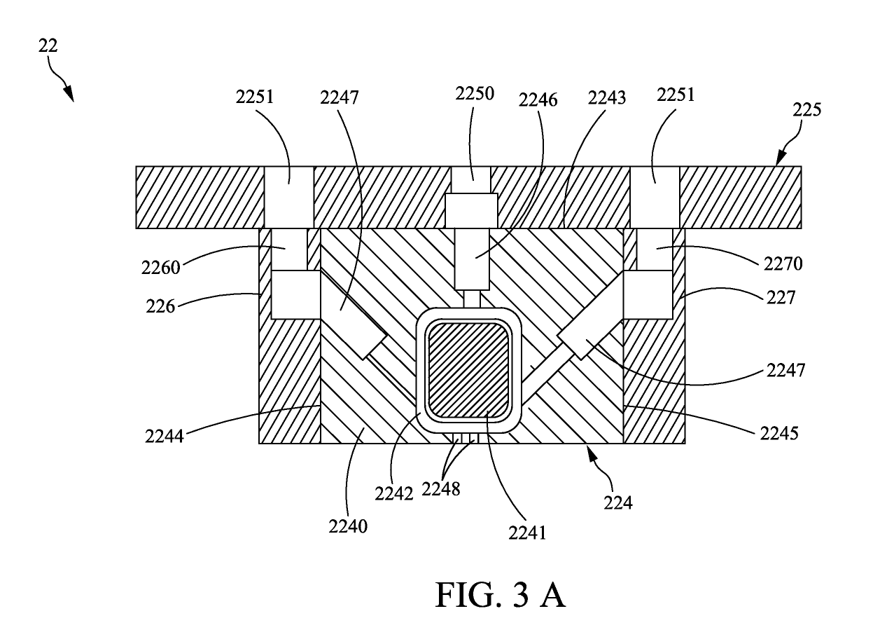

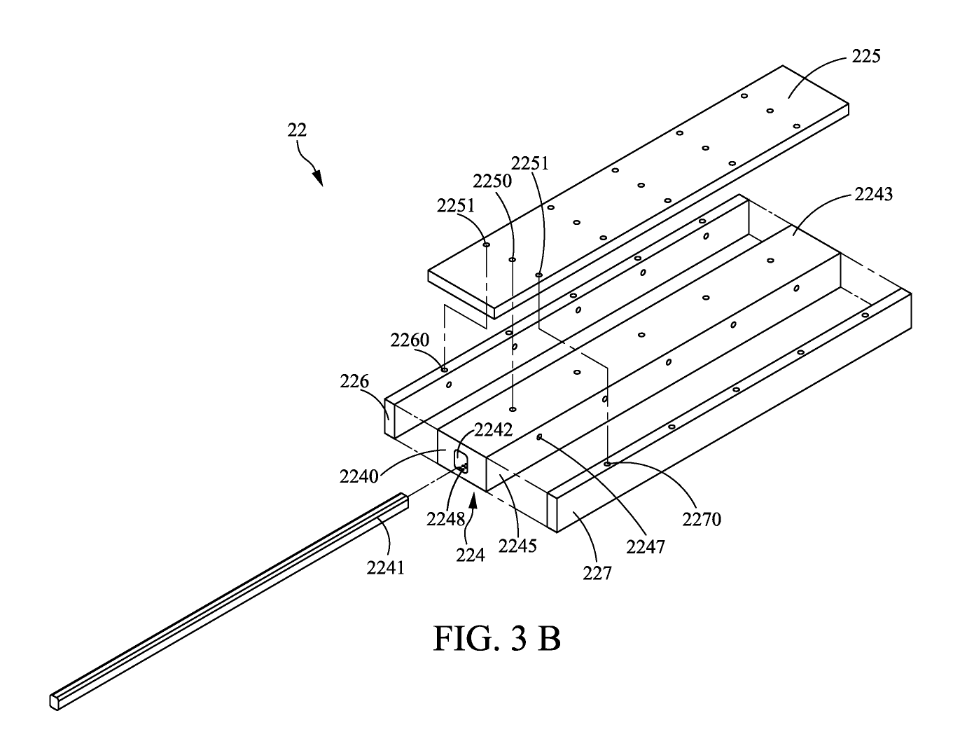

FIGS. 3A and 3B respectively illustrate a cross-sectional and a three-dimensional exploded views of the plasma generator 22 according to a second exemplary embodiment. In the embodiment, the plasma generator 22 is composed of a plasma module 224 with a negative electrode 2240 and a positive electrode 2241. The structures of the accommodating channel 2242 on the negative electrode 2240 and the positive electrode 2241 are the same as the accommodating channel 2204 and positive electrode 2202 in the foregoing embodiment, and won't be depicted here again. A first gas via 2246 connected to the accommodating channel 2242 is formed on the upper facet 2243 of the negative electrode 2240, and a plurality of second gas vias 2247 respectively connected to the right and left sides of the accommodating channel 2242 are respectively formed on the right 2245 and left facets 2244. Through holes 2248 are formed between the accommodating channel 2242 and one of the facets of the negative electrode 2240 to provide passing paths for the plasma.

A cover plate 225 is disposed on the facet 2243, whereon multiple first 2250 and second 2251 gas entrance holes 2250 are formed. Each pair of the second gas entrance holes 2251 are arranged by each of the first gas entrance holes 2250. Two side plates 226 and 227, having respective guiding paths 2260 and 2270 therein, are respectively set on the facets 2244 and 2245. The first gas entrance holes 2250 are respectively connected to the first gas via 2246, while the second gas entrance holes 2251 are respectively connected to the second gas vias 2247 through respective guiding paths 2260 and 2270.

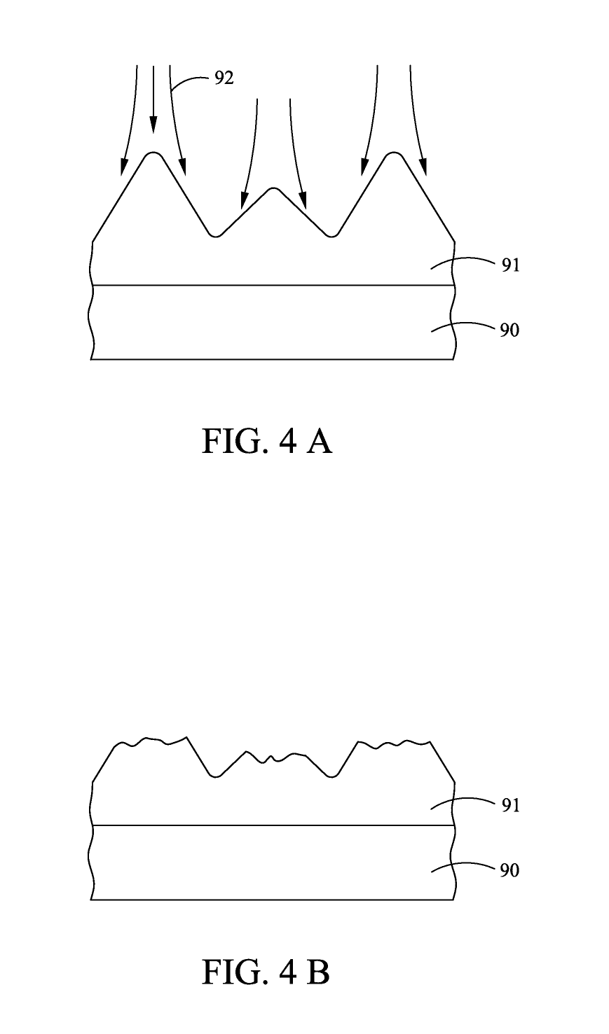

The control unit 23, as shown in FIG. 1A, is electrically connected to the plasma generator 22 to control the generation of the plasma. The plasma is used to implement the surface flattening process on the deposition layer on the substrate 90 that is carried from the reaction chamber 20 to carrying chamber 21. For example, when the substrate 90 with a deposition layer 91 as shown in FIG. 4A passes the thin-rectangle-shaped plasma generator 22, the generated plasma 92 scans the substrate 90 to etch the raised part of the deposition layer 91. The processed deposition layer 91 may be schematically illustrated in FIG. 4B, where the raised sharp parts are flattened. As in FIG. 1A, it is noted that the plasma of the plasma generator 22 in the embodiment can also clean a substrate 90 when the substrate 90 is carried from the carrying chamber 21 to the reaction chamber 20, so as to improve the deposition conditions in the following fabrication process.

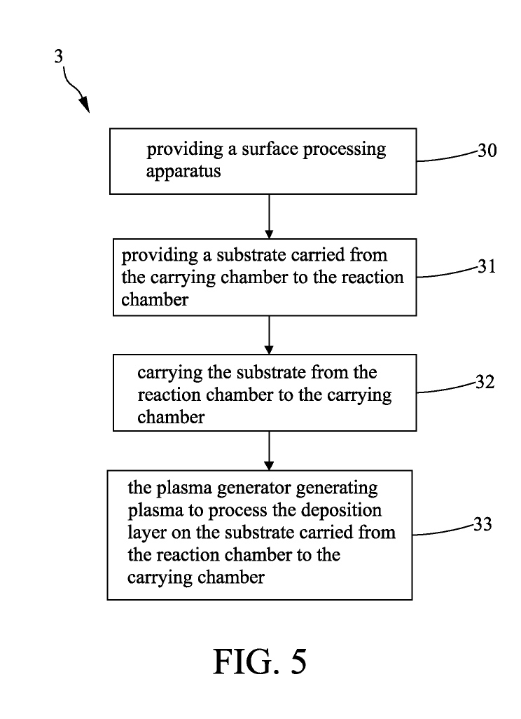

FIG. 5 schematically shows a flowchart of a surface processing method according to an embodiment of the present disclosure. At first, in step 30 a surface processing apparatus is provided. The surface processing apparatus is schematically shown in FIG. 1A or 1C and depicted as in the foregoing paragraphs. Then in step 31 a substrate is provided and carried from the carrying chamber to the reaction chamber, and a deposition layer can be formed on the substrate after a film deposition process. In the step, the substrate to be processed is taken out from an external substrate-carrying device, such as a wafer cassette, and is carried by a carrying means 215 from the carrying chamber 21 to the reaction chamber 20. The film deposition can be processed by LPCVD, but is not limited thereby. Then in step 32, the substrate is carried from the reaction chamber 20 to the carrying chamber 21 by the carrying means 215. Then in step 33, when the substrate passes by the plasma generator 22, the plasma is generated to flatten the deposition layer on the substrate. Moreover, when the substrate is carried from the carrying chamber 21 to the reaction chamber 20, the method further comprises a step of having the plasma generator 22 generate the plasma to clean the surface of the substrate.

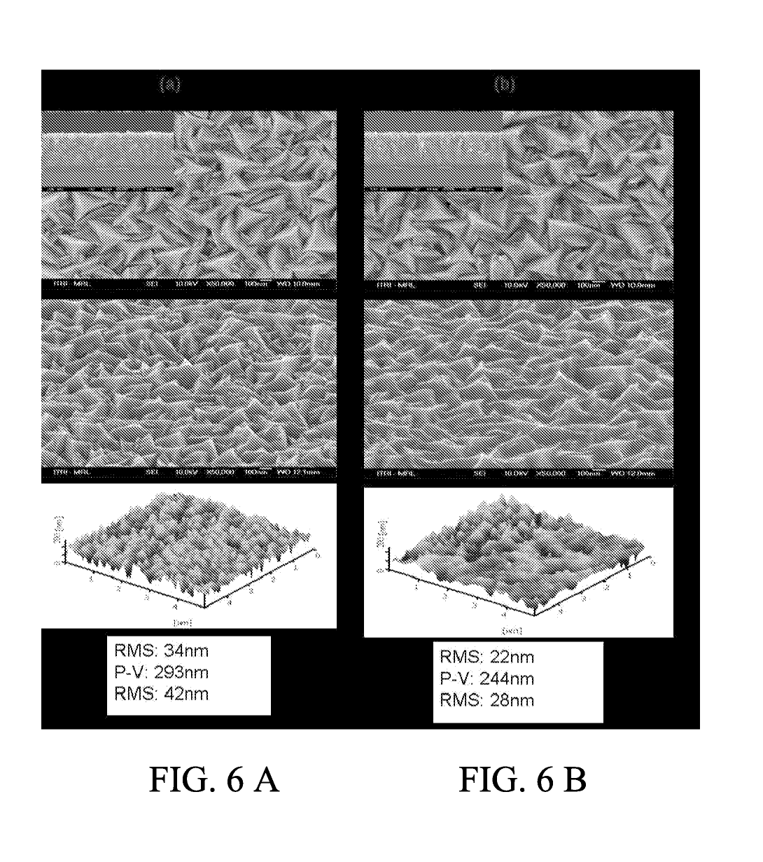

FIGS. 6A and 6B are the measured data of the deposited layers with and without the proposed surface processing method of the embodiment. In FIG. 6A, only the LPCVD is used to deposit the film and the RMS (root mean square) surface roughness thereof is measured 34-42 nm However, with the proposed surface process, the RMS surface roughness can be reduced to 24-28 nm, and that shows a quite great improvement in the surface quality. The electric power used in the plasma generator 22 is a pulsed DC power with an operating frequency of 30 kHz. The input voltage is 2 kV at a constant-power operation, and the distance between the substrate and the plasma generator 22 is 3 mm. It is noted that the starting voltage of the power generator depends on the distance between the deposition layer and the plasma generator; consequently, the operational parameters can be designated according to the practical needs, but is not limited at the foregoing distance of 3 mm

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A surface processing apparatus, comprising:
a reaction chamber provided to form a deposition layer on a substrate and having a first opening;
a carrying chamber connected to the reaction chamber and comprising a slot, a second opening corresponding to the first opening, and a carrying means provided inside the carrying chamber to carry the substrate from the carrying chamber to the reaction chamber or from the reaction chamber to the carrying chamber;
a plasma generator installed on the slot; and
a control unit electrically connected to the plasma generator and provided to control the plasma generator to generate plasma;
wherein the plasma processes the deposition layer on the substrate carried from the reaction chamber to the carrying chamber.

2. The surface processing apparatus of claim 1, wherein the plasma generator is thin rectangle-shaped and comprises a plasma module having a negative and a positive electrodes, the negative electrode shaped as a rectangular solid installed inside the slot and having an accommodating channel, multiple first gas vias connected to the accommodating channel, and multiple through holes connected to the accommodating channel and arranged in lines on a first facet, the accommodating channel provided to accommodate the positive electrode, the positive electrode coated with a dielectric layer.

3. The surface processing apparatus of claim 2, wherein the negative electrode further comprises a gas balancing groove and a cover, the gas balancing groove installed on a second facet opposite to the first facet and connected to the first gas vias, the cover installed on the gas balancing groove and having multiple gas entrance holes connected to the gas balancing groove.

4. The surface processing apparatus of claim 2, wherein the accommodating channel further comprises multiple second gas vias on two opposite sides thereof.

5. The surface processing apparatus of claim 4, wherein the accommodating channel further comprises a cover plate having multiple first and second gas entrance holes, the first gas entrance holes respectively corresponding to the first gas vias, the second gas entrance holes respectively corresponding to the second gas vias.

6. The surface processing apparatus of claim 2, wherein the negative electrode further comprises a cooling unit having at least one cooling piping and installed on two opposite sides of the accommodating channel.

7. The surface processing apparatus of claim 1, wherein the carrying chamber further comprises a metal plate installed in a place corresponding to the plasma generator.

8. The surface processing apparatus of claim 1, wherein the plasma cleans surface of the substrate carried from the carrying chamber to the reaction chamber.

9. The surface processing apparatus of claim 1, wherein an LPCVD process is provided in the reaction chamber to form the deposition layer.

10. The surface processing apparatus of claim 1, wherein the plasma generator is provided to generate plasma in atmospheric or vacuum conditions.

11. The surface processing apparatus of claim 1, wherein the plasma generator is provided with a pulsed DC power with an operational frequency of 30 kHz, an operational voltage of 2 kV at a constant-power operational mode, and a distance of 3 mm between the substrate and the plasma generator.

12. A surface processing method, comprising:
providing a surface processing apparatus comprising a reaction chamber, a carrying chamber, and a plasma generator, the carrying chamber connected to the reaction chamber and comprising a slot, the plasma generator installed on the slot;
providing a substrate carried from the carrying chamber to the reaction chamber;
carrying the substrate from the reaction chamber to the carrying chamber; and
the plasma generator generating plasma to process the deposition layer on the substrate carried from the reaction chamber to the carrying chamber.

13. The surface processing method of claim 12, wherein the plasma generator is thin rectangle-shaped and comprises a plasma module having a negative and a positive electrodes, the negative electrode shaped as a rectangular solid installed inside the slot and having an accommodating channel, multiple first gas vias connected to the accommodating channel, and multiple through holes connected to the accommodating channel and arranged in lines on a first facet, the accommodating channel provided to accommodate the positive electrode, the positive electrode coated with a dielectric layer.

14. The surface processing method of claim 13, wherein the negative electrode further comprises a gas balancing groove and a cover, the gas balancing groove installed on a second facet opposite to the first facet and connected to the first gas vias, the cover installed on the gas balancing groove and having multiple gas entrance holes connected to the gas balancing groove.

15. The surface processing method of claim 13, wherein the accommodating channel further comprises multiple second gas vias on two opposite sides thereof.

16. The surface processing method of claim 15, wherein the accommodating channel further comprises a cover plate having multiple first and second gas entrance holes, the first gas entrance holes respectively corresponding to the first gas vias, the second gas entrance holes respectively corresponding to the second gas vias.

17. The surface processing method of claim 13, wherein the negative electrode further comprises a cooling unit having at least one cooling piping and installed on two opposite sides of the accommodating channel.

18. The surface processing method of claim 12, wherein the carrying chamber further comprises a metal plate installed in a place corresponding to the plasma generator.

19. The surface processing method of claim 12, wherein the plasma cleans surface of the substrate carried from the carrying chamber to the reaction chamber.

20. The surface processing method of claim 12, wherein the plasma generator is provided to generate plasma in atmospheric or vacuum conditions.

21. The surface processing method of claim 12, wherein the plasma generator is provided with a pulsed DC power with an operational frequency of 30 kHz, an operational voltage of 2 kV at a constant-power operational mode, and a distance of 3 mm between the substrate and the plasma generator.
